(19) United States
(12) Patent Application Publication
(10) Pub. No.: US 2026/0323934 A1
(43) Pub. Date: Oct. 15, 2026

(54) SEMICONDUCTOR MEMORY DEVICE

(71) Applicant: Samsung Electronics Co., Ltd., Suwon-si (KR)

(72) Inventors: Hyeon Woo Jeong, Suwon-si (KR); Min Hyeok Kong, Suwon-si (KR); Hyung Min Ko, Suwon-si (KR)

(73) Assignee: Samsung Electronics Co., Ltd., Suwon-si (KR)

(21) Appl. No.: 19/646,492

(22) Filed: Apr. 13, 2026

(30) Foreign Application Priority Data
Apr. 14, 2025 (KR) 10-2025-0048273

(51) Int. Cl. H10B 12/00; H10W 20/41; H10W 20/42; H10W 20/44

(52) U.S. Cl. CPC H10B 12/50; H10B 12/315; H10B 12/34; H10B 12/482; H10W 20/422; H10W 20/435; H10W 20/4441

(57) ABSTRACT

Provided is a semiconductor memory device. The semiconductor memory device according to some embodiments of the present disclosure includes a substrate which includes a cell region, and a peri region defined around the cell region, the cell region including a cell active region defined by a cell element separation film, a plurality of bit line structures which extend in a first horizontal direction on each of the cell element separation film and the cell active region, a storage contact which is connected to the cell active region between the plurality of bit line structures, a first storage pad which is connected to the storage contact, on the storage contact, a data storage pattern which is connected to the first storage pad, a peri gate structure which is disposed on the substrate of the peri region, and a peri contact plug which is disposed on both sides of the peri gate structure, and connected to the substrate, wherein the first storage pad includes a first silicide film on the storage contact, and a first conductive film on the first silicide film, the peri contact plug includes a recess that extends into the substrate in a vertical direction, a second silicide film on a bottom side of the recess, a second conductive film that extends along a side wall of the recess on the second silicide film, and a third conductive film that fills the inside of the recess on the second conductive film, and a width of the first conductive film is different from a width of the second conductive film, in a second horizontal direction different from the first horizontal direction.

### CROSS-REFERENCE TO RELATED APPLICATIONS

This present application claims priority to and the benefit under 35 U.S.C. § 119(a)-(d) of Korean Patent Application No. 10-2025-0048273, filed on Apr. 14, 2025, in the Korean Intellectual Property Office, the entire disclosure of which is incorporated herein by reference.

### FIELD

The present disclosure relates to a semiconductor memory device.

### BACKGROUND

Electronic devices are becoming smaller and lighter in response to the rapid development of electronics industry and the demands of users. Therefore, semiconductor elements having a high degree of integration used in the electronic devices are required, and the design rules for the configurations of the semiconductor elements are decreasing.

### SUMMARY

Aspects of the present disclosure provide a semiconductor memory device having improved performance and reliability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

A semiconductor memory device according to some embodiments of the present disclosure includes a substrate which includes a cell region, and a peri region defined around the cell region, the cell region including a cell active region defined by a cell element separation film, a plurality of bit line structures which extend in a first horizontal direction on each of the cell element separation film and the cell active region, a storage contact which is connected to the cell active region between the plurality of bit line structures, a first storage pad which is connected to the storage contact, on the storage contact, a data storage pattern which is connected to the first storage pad, a peri gate structure which is disposed on the substrate of the peri region, and a peri contact plug which is disposed on both sides of the peri gate structure, and connected to the substrate, wherein the first storage pad includes a first silicide film on the storage contact, and a first conductive film on the first silicide film, the peri contact plug includes a recess that extends into the substrate in a vertical direction, a second silicide film on a bottom side of the recess, a second conductive film that extends along a side wall of the recess on the second silicide film, and a third conductive film that fills the inside of the recess on the second conductive film, and a width of the first conductive film is different from a width of the second conductive film, in a second horizontal direction different from the first horizontal direction.

A semiconductor memory device according to some embodiments of the present disclosure includes a substrate which includes a cell region, and a peri region defined around the cell region, the cell region including a cell active region defined by a cell element separation film, a plurality of cell conductive lines which extend in a horizontal direction on each of the cell element separation film and the cell active region, a storage contact which is connected to the cell active region between the plurality of cell conductive lines, a first storage pad which is connected to the storage contact, on the storage contact, a data storage pattern which is connected to the first storage pad, a second storage pad between the first storage pad and the data storage pattern, a peri gate structure which is disposed on the substrate of the peri region, a peri contact plug which is disposed on both sides of the peri gate structure, and connected to the substrate, and a peri wiring line which is connected to the peri contact plug, on the peri gate structure, wherein the first storage pad includes a first silicide film on the storage contact, and a first conductive film on the first silicide film, the peri contact plug includes a recess that extends into the substrate in a vertical direction, a second silicide film on a bottom side of the recess, a second conductive film that extends along a side wall of the recess on the second silicide film, and a third conductive film that fills the inside of the recess on the second conductive film, and a thickness of the first conductive film is greater than a thickness of the second storage pad in the vertical direction.

A semiconductor memory device according to some embodiments of the present disclosure includes a substrate which includes a cell region, and a peri region defined around the cell region, the cell region including a cell active region defined by a cell element separation film, a plurality of bit line structures which extend in a horizontal direction on each of the cell element separation film and the cell active region, a storage contact which is connected to the cell active region of the cell region between the plurality of bit line structures, a storage pad structure which is connected to the storage contact, on the storage contact, a data storage pattern which is connected to the storage pad structure, a peri gate structure which is disposed on the substrate of the peri region, an interlayer insulating film which is disposed on the peri gate structure, a peri contact plug which is disposed on both sides of the peri gate structure, penetrates the interlayer insulating film, and is connected to the substrate, and a peri wiring line which is connected to the peri contact plugs, on the peri gate structure, wherein the storage pad structure includes a first storage pad on the storage contact, and a second storage pad between the first storage pad and the data storage pattern, the first storage pad includes a first silicide film on the storage contact, and a first conductive film on the first silicide film, the peri contact plug includes a recess that extends into the substrate in a vertical direction, a second silicide film on a bottom side of the recess, a second conductive film that extends along a side wall of the recess on the second silicide film, and a third conductive film that fills the inside of the recess on the second conductive film, an upper side of the bit line structure is located at a same vertical level as an upper side of the interlayer insulating film, an upper side of the second storage pad is located at a same vertical level as an upper side of the peri wiring line, each of the first conductive film and the second conductive film includes titanium nitride (TiN), and each of the second storage pad and the third conductive film includes tungsten (W).

A method for fabricating a semiconductor memory device according to some embodiments of the present disclosure includes providing a substrate which includes a cell region, and a peri region defined around the cell region, forming a cell active region defined by a cell element separation film, in the substrate of the cell region, forming a plurality of bit line structures on the cell element separation film and the cell active region, forming a peri gate structure on the substrate of the peri region, forming a storage contact connected to the cell active region between the plurality of bit line structures, forming a first silicide film, and a first conductive film on the first silicide film, on the storage contact, forming a cell protective film on the first conductive film of the cell region, forming a recess that extends into the substrate, on both sides of the peri gate structure, forming a second silicide film on a bottom side of the recess, and a pre-second conductive film that extends along a side wall of the recess on the second silicide film, forming a pre-third conductive film that fills the inside of the recess, on the pre-second conductive film, removing the cell protective film of the cell region, removing at least a part of the pre-second conductive film and the pre-third conductive film of the peri region to form a second conductive film and a third conductive film, forming a pre-fourth conductive film on the first conductive film of the cell region, forming a pre-fifth conductive film on the third conductive film of the peri region, patterning the pre-fourth conductive film of the cell region to form a fourth conductive film, and patterning the fifth conductive film of the peri region to form a fifth conductive film.

Specific details of other embodiments are included in the detailed description and drawings.

### BRIEF DESCRIPTION OF DRAWINGS

The and other aspects and features of the present disclosure will become more apparent by describing in detail illustrative embodiments thereof with reference to the attached drawings, in which:

FIG. 1 is a schematic layout diagram of a semiconductor memory device according to some embodiments;

FIG. 2 is a layout of an R region, which is a part of a cell region of FIG. 1;

FIG. 3 is a layout showing only word lines and active regions of FIG. 2;

FIG. 4 is a cross-sectional view taken along A-A of FIG. 2;

FIG. 5 is a cross-sectional view taken along B-B of FIG. 1;

FIG. 6 is a cross-sectional view taken along C-C of FIG. 2;

FIG. 7 is a layout diagram for explaining a semiconductor memory device according to some embodiments;

FIG. 8 is a perspective view for explaining a semiconductor memory device according to some embodiments;

FIG. 9 is a cross-sectional view taken along lines D-D and E-E of FIG. 7;

FIG. 10 is a layout diagram for explaining a semiconductor memory device according to some embodiments;

FIG. 11 is a perspective view for explaining the semiconductor memory device according to some embodiments;

FIG. 12 is a diagram for explaining the semiconductor memory device according to some embodiments;

FIGS. 13 to 20 are intermediate step diagrams for explaining a method for fabricating a semiconductor memory device according to some embodiments.

### DETAILED DESCRIPTION

Although terms such as first and second are used to describe various elements or components in the present specification, it goes without saying that these elements or components are not limited by these terms. These terms are only used to distinguish a single element or component from other elements or components. Therefore, it goes without saying that a first element or component referred to below may be a second element or component within the technical idea of the present disclosure.

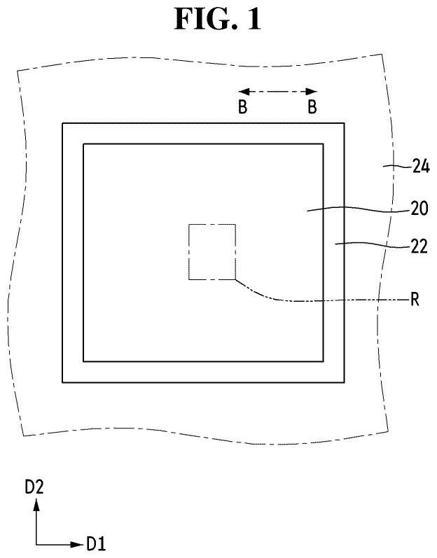

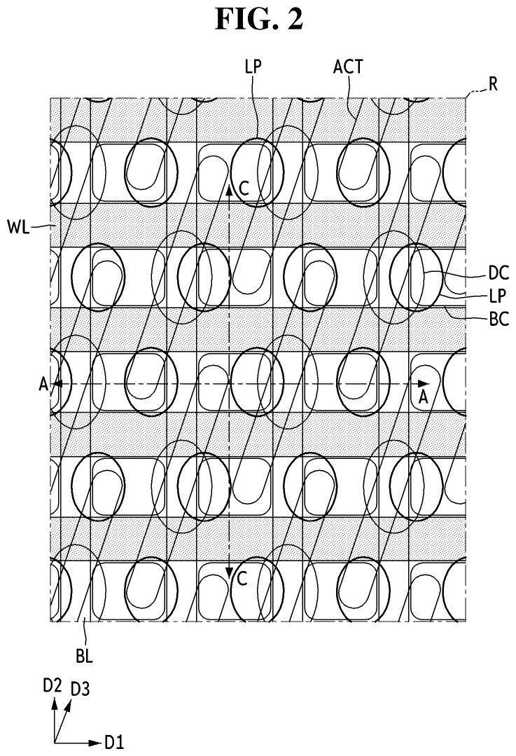

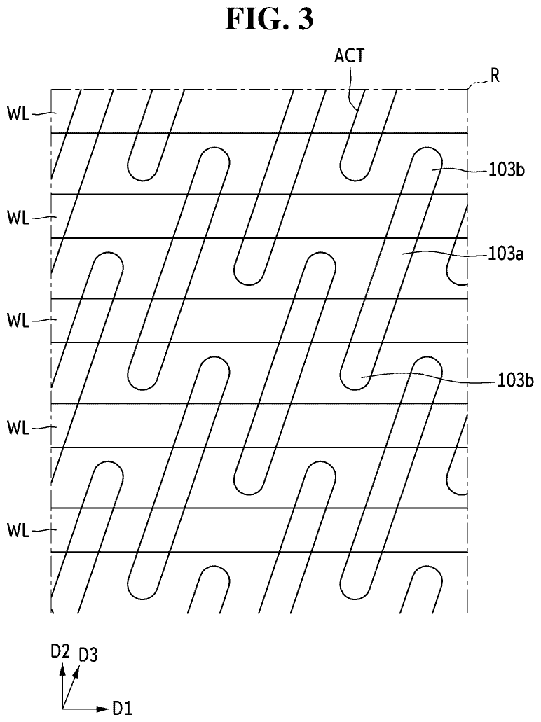

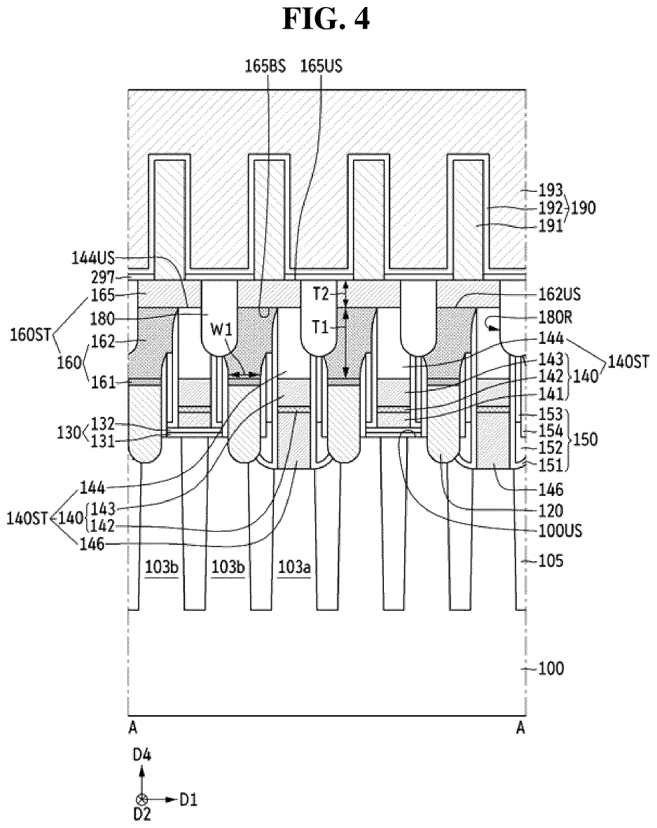

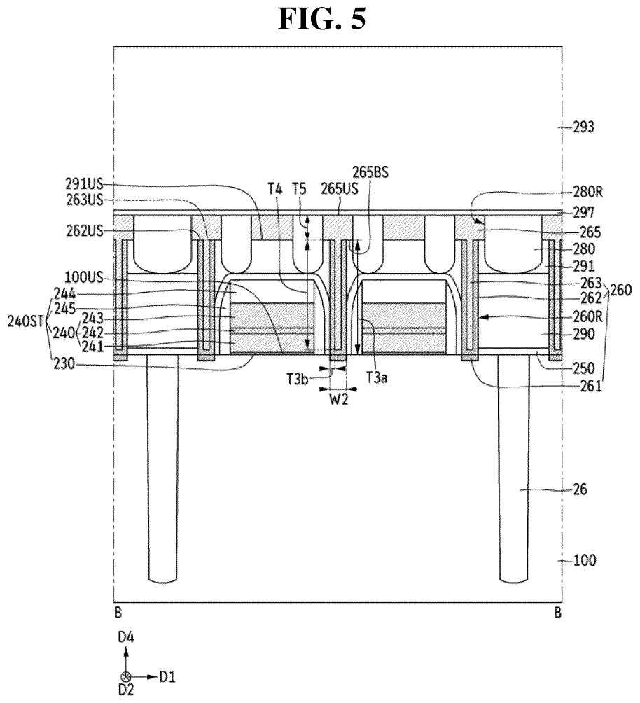

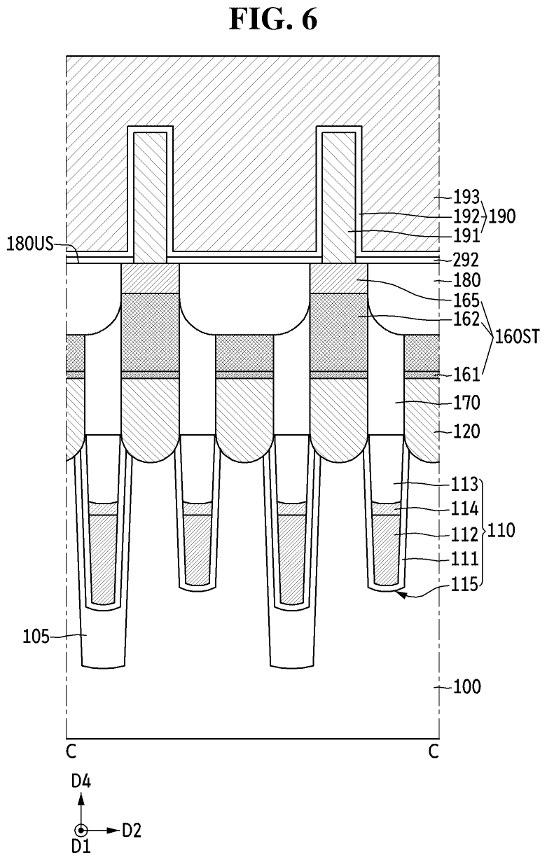

FIG. 1 is a schematic layout diagram of a semiconductor memory device according to some embodiments. FIG. 2 is a layout of an R region, which is a part of a cell region of FIG. 1. FIG. 3 is a layout showing only word lines and active regions of FIG. 2. FIG. 4 is a cross-sectional view taken along A-A of FIG. 2. FIG. 5 is a cross-sectional view taken along B-B of FIG. 1. FIG. 6 is a cross-sectional view taken along C-C of FIG. 2.

For reference, FIG. 5 may be an exemplary cross-sectional view taken through a transistor formation region of a peri region. Although a cutting line B-B is indicated as being cut along a first direction D1 in FIG. 1, the embodiment is not limited thereto. Unlike the shown example, the cutting line B-B may be indicated as being cut along a second direction D2.

In the diagrams relating to the semiconductor memory device according to some embodiments, although a dynamic random access memory (DRAM) is shown as an example, the embodiment is not limited thereto.

With reference to FIGS. 1 to 3, the semiconductor memory device according to some embodiments may include a cell region 20, a cell region separation film 22, and a peri region 24.

The cell region separation film 22 may be formed along the periphery of the cell region 20. The cell region separation film 22 may separate the cell region 20 from the peri region 24. The peri region 24 may be defined around the cell region 20.

The cell region 20 may include a plurality of cell active regions ACT. The cell active regions ACT may be defined by a cell element separation film (105 of FIG. 4) formed in a substrate (100 of FIG. 4). As the design rule of the semiconductor memory device decreases, the cell active region ACT may be disposed in the form of a bar of a diagonal line or an oblique line, as shown. For example, the cell active region ACT may extend in a third direction D3.

A plurality of gate electrodes may be disposed in the first direction D1 across the cell active region ACT. The plurality of gate electrodes may extend parallel to each other. The plurality of gate electrodes may be, for example, a plurality of word lines WL. The word lines WL may be disposed at equal intervals. The width of the word lines WL or the interval between the word lines WL may be determined depending on the design rule.

Each cell active region ACT may be divided into three portions by two word lines WL extending in the first direction D1. The cell active region ACT may include a bit line connecting region 103a and a storage connecting region 103b. The bit line connecting region 103a may be located in the central portion of the cell active region ACT, and the storage connecting region 103b may be located at the end part of the cell active region ACT.

A plurality of bit lines BL extending in the second direction D2 orthogonal to the word line WL may be disposed on the word line WL. The plurality of bit lines BL may extend to be parallel to each other. The bit lines BL may be disposed at regular intervals. A width of the bit lines BL or an interval between the bit lines BL may be determined depending on design rules.

A semiconductor memory device according to some embodiments may include various contact arrangements formed on the cell active region ACT. Various contact arrangements may include, for example, a direct contact (DC), a buried contact (BC), a landing pad (LP), and the like.

Here, the direct contact DC may mean a contact that electrically connects the cell active region ACT to the bit line BL. The buried contact BC may mean a contact that connects the cell active region ACT to a lower electrode (191 of FIG. 4) of the capacitor. A contact area between the buried contact BC and the cell active region ACT may be small due to the placement structure. Therefore, a conductive landing pad LP may be introduced to enlarge the contact area with the cell active region ACT and enlarge the contact area with the lower electrode (191 of FIG. 4) of the capacitor.

The landing pad LP may be disposed between the buried contact BC and the lower electrode (191 of FIG. 4) of the capacitor, or may be disposed between the cell active region ACT and the buried contact BC. In the semiconductor memory device according to some embodiments, the landing pad LP may be disposed between the buried contact BC and the lower electrode 191 of the capacitor. By enlarging the contact area through the introduction of the landing pad LP, the contact resistance between the cell active region ACT and the lower electrode 191 of the capacitor may decrease.

The direct contact DC may be connected to the bit line connecting region 106a. The buried contact BC may be connected to the storage connecting region 106b. As the buried contact BC is disposed at both end portions of the cell active region ACT, the landing pad LP may be disposed adjacent to both ends of the cell active region ACT to partially overlap the buried contact BC. In other words, the buried contact BC may be formed to overlap the cell active region ACT and the cell element separation film (105 of FIG. 4) between the adjacent word lines WL and between the adjacent bit lines BL.

The word line WL may be formed as a structure buried inside the substrate 100. The word line WL may be disposed across the cell active region ACT between the direct contact DC and the buried contact BC. As shown, two word lines WL may be disposed to cross one active region ACT. Since the cell active region ACT extends along the third direction D3, the word line WL may have an angle less than 90 degrees with the cell active region ACT.

The direct contact DC and the buried contact BC may be disposed symmetrically. Therefore, the direct contact DC and the buried contact BC may be disposed on a straight line along the first direction D1 and the third direction D2.

Meanwhile, unlike the direct contact DC and the buried contact BC, the landing pads LP may be disposed in a zigzag manner in the second direction D2 in which the bit line BL extends. Also, the landing pads LP may be disposed to overlap the same side face portions of each bit line BL in the first direction D1 in which the word line WL extends.

For example, each of the landing pads LP of the first line may overlap a left side of the corresponding bit line BL, and each of the landing pads LP of the second line may overlap a right side of the corresponding bit line BL.

Referring to FIGS. 1 to 6, the semiconductor memory device according to some embodiments may include a plurality of cell gate structures 110, a plurality of bit line structures 140ST, a plurality of storage contacts 120, a plurality of storage pad structures 160ST, a data storage pattern 190, a peri gate structure 240ST, a peri contact plug 260, and a peri wiring line 265.

The substrate 100 may include a cell region 20, a cell region separation film 22, and a peri region 24. The substrate 100 may be a silicon substrate or a silicon-on-insulator (SOI). In contrast, the substrate 100 may include, but is not limited to, silicon germanium, silicon germanium on insulator (SGOI), indium antimonide, lead telluride, indium arsenide, indium phosphide, gallium arsenide or gallium antimonide.

A plurality of cell gate structures 110, a plurality of bit line structures 140ST, a plurality of storage contacts 120, a plurality of storage pads 160, and a data storage pattern 190 may be disposed in the cell region 20. The peri gate structure 240ST, the peri contact plug 260, and the peri wiring line 265 may be disposed in the peri region 24.

The cell element separation film 105 may be formed in the substrate 100 of the cell region 20. The cell element separation film 105 may have a shallow trench isolation (STI) structure having excellent isolation characteristics. The cell element separation film 105 may define a cell active region ACT in the cell region 20. The cell active region ACT defined by the cell element separation film 105 may have a long island shape including a short axis and a long axis as shown in FIGS. 2 and 3. The cell active region ACT may have an oblique line shape to have an angle of less than 90 degrees with respect to the word line WL formed in the cell element separation film 105. Further, the cell active region ACT may have an oblique line shape to have an angle of less than 90 degrees with respect to the bit line BL formed on the cell element separation film 105.

The cell region separation film 22 may also have an STI structure. The cell region 20 may be defined by the cell region separation film 22.

Each of the cell element separation film 105 and the cell region separation film 22 may include, for example, but are not limited to, at least one of a silicon oxide film, a silicon nitride film, and a silicon oxynitride film. In FIGS. 4 and 6, although the cell element separation film 105 is shown to be formed of one insulating film, this is only for convenience of explanation and the embodiment is not limited thereto. Depending on the widths of the cell element separation film 105 and the cell region separation film 22, each of the cell element separation film 105 and the cell region separation film 22 may be formed of one insulating film or a plurality of insulating films.

Although the upper side of the cell element separation film 105 and the upper side of the substrate 100 are shown as being placed on the same plane in FIGS. 4 and 6, this is only for convenience of explanation and the embodiment is not limited thereto.

The cell gate structure 110 may be disposed inside the substrate 100 and the cell element separation film 105. The gate structure 110 may be disposed across the cell element separation film 105, and the cell active region ACT defined by the cell element separation film 105. The cell gate structure 110 may include a cell gate trench 115, a cell gate insulating film 111, a cell gate electrode 112, a cell gate capping pattern 113, and a cell gate capping conductive film 114 which are formed inside the substrate 100 and the cell element separation film 105. Here, the cell gate electrode 112 may correspond to the word line WL. Unlike the shown example, the cell gate structure 110 may not include the cell gate capping conductive film 114.

The cell gate trench 115 may be relatively deep in the cell element separation film 105 and relatively shallow in the cell active region ACT. A bottom side of the cell gate electrode 112 may be curved. That is, the depth of the cell gate trench 115 in the cell element separation film 105 may be greater than the depth of the cell gate trench 115 in the cell active region ACT.

The cell gate insulating film 111 may extend along the side wall and bottom side of the cell gate trench 115. The cell gate insulating film 111 may extend along the profile of at least a part of the cell gate trench 115. The cell gate insulating film 111 may include, for example, at least one of silicon oxide, silicon nitride, silicon oxynitride, or a high dielectric constant material having a higher dielectric constant than silicon oxide. The high dielectric constant material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

The cell gate electrode 112 may be formed on the cell gate insulating film 111. The cell gate electrode 112 may fill a part of the cell gate trench 115. The cell gate capping conductive film 114 may extend along an upper side of the cell gate electrode 112.

The cell gate electrode 112 may include at least one of a metal, a conductive metal nitride, a conductive metal carbonitride, a conductive metal carbide, a metal silicide, a doped semiconductor material, a conductive metal oxynitride, and a conductive metal oxide. The cell gate electrode 112 may include, for example, but is not limited to, at least one of TiN, TaC, TaN, TiSiN, TaSiN, TaTiN, TiAlN, TaAlN, WN, Ru, TiAl, TiAlC-N, TiAlC, TiC, TaCN, W, Al, Cu, Co, Ti, Ta, Ni, Pt, Ni-Pt, Nb, NbN, NbC, Mo, MON, MOC, WC, Rh, Pd, Ir, Ag, Au, Zn, V, RuTiN, TiSi, TaSi, NiSi, CoSi, IrOx, RuOx and combinations thereof. The cell gate capping conductive film 114 may include, for example, but is not limited to, polysilicon or polysilicon-germanium.

The cell gate capping pattern 113 may be disposed on the cell gate electrode 112 and the cell gate capping conductive film 114. The cell gate capping pattern 113 may fill the cell gate trench 115 that remains after the cell gate electrode 112 and the cell gate capping conductive film 114 are formed. Although the cell gate insulating film 111 is shown to extend along the side wall of the cell gate capping pattern 113, the embodiment is not limited thereto.

The cell gate capping pattern 113 may include, for example, at least one of silicon nitride (SiN), silicon oxynitride (SiON), silicon oxide (SiO₂), silicon carbonitride (SiCN), silicon oxycarbonitride (SiOCN) and combinations thereof.

Although not shown, an impurity doped region may be formed on at least one side of the cell gate structure 110. The impurity doped region may be a source/drain region of a transistor.

The bit line structure 140ST may include a cell conductive line 140 and a cell line capping film 144. The cell conductive line 140 may be disposed on the substrate 100 and the cell element separation film 105 on which the cell gate structure 110 is disposed.

The cell conductive line 140 may extend in the second direction D2. The cell conductive line 140 may intersect the cell element separation film 105, and the cell active region ACT defined by the cell element separation film 105. The cell conductive line 140 may be formed to intersect the cell gate structure 110. Here, the cell conductive line 140 may correspond to the bit line BL.

The cell conductive line 140 may be a multi-layer film. The cell conductive line 140 may include, for example, a first cell conductive film 141, a second cell conductive film 142, and a third cell conductive film 143. The first to third cell conductive films 141, 142, and 143 may be sequentially stacked on the substrate 100 and the cell element separation film 105. Although the cell conductive line 140 is shown as being a triple film, the embodiment is not limited thereto.

Each of the first to third cell conductive films 141, 142, and 143 may include at least one of a semiconductor material doped with impurity, a conductive silicide compound, a conductive metal nitride, a two-dimensional material (2D material), and a metal. In the semiconductor memory device according to some embodiments, the two-dimensional material may be a metallic material and/or a semiconductor material. The two-dimensional material (2D material) may include a two-dimensional allotrope or a two-dimensional compound, and may include, for example, but is not limited to, at least one of graphene, molybdenum disulfide (MoS₂), molybdenum diselenide (MoSe₂), tungsten diselenide (WSe₂), and tungsten disulfide (WS₂). That is, the above-mentioned two-dimensional materials are merely listed as examples, and the two-dimensional materials that may be included in the semiconductor memory device of the present disclosure are not limited to the above-mentioned materials.

For example, the first cell conductive film 141 may include a doped semiconductor material, the second cell conductive film 142 may include at least one of a conductive silicide compound, a conductive metal nitride, and a two-dimensional material, and the third cell conductive film 143 may include, but is not limited to, a metal.

The bit line contact 146 may be disposed between the cell conductive line 140 and the substrate 100. That is, the cell conductive line 140 may be disposed on the bit line contact 146. For example, the bit line contact 146 may be formed at a point on which the cell conductive line 140 intersects a central portion of the cell active region ACT having a long island shape. The bit line contact 146 may be disposed between the bit line connecting region 103a and the cell conductive line 140.

The bit line contact 146 may electrically connect the cell conductive line 140 and the substrate 100. Here, the bit line contact 146 may correspond to the direct contact DC. The bit line contact 146 may include, for example, at least one of a semiconductor material doped with impurity, a conductive silicide compound, a conductive metal nitride, and a metal.

In FIG. 4, in the region that overlaps the upper side of the bit line contact 146, the cell conductive line 140 may include a second cell conductive film 142 and a third cell conductive film 143. In the region which does not overlap the upper side of the bit line contact 146, the cell conductive line 140 may include first to third cell conductive films 141, 142, and 143. The thickness of the cell conductive line 140 in the region which overlaps the upper side of the bit line contact 146 may be different from the thickness of the cell conductive line 140 in the region which does not overlap the upper side of the bit line contact 146 The cell line capping film 144 may be disposed on the cell conductive line 140. The cell line capping film 144 may extend in the second direction D2 along the upper side of the cell conductive line 140. At this time, the cell line capping film 144 may include at least one of, for example, a silicon nitride film, a silicon oxynitride, a silicon carbonitride, and a silicon oxycarbonitride. In the semiconductor memory device according to some embodiments, the cell line capping film 144 may include, for example, a silicon nitride film. Although the cell line capping film 144 is shown as being a single film, the embodiment is not limited thereto. That is, the cell line capping film 144 may be a multi-layer film. However, if each film constituting the multi-layer film is made of the same material, the cell line capping film 144 may be considered as a single film.

The cell insulating film 130 may be disposed on the substrate 100 and the cell element separation film 105. More specifically, the cell insulating film 130 may be disposed on the substrate 100 and the cell element separation film 105 in which the bit line contact 146 is not formed. The cell insulating film 130 may be disposed between the substrate 100 and the cell conductive line 140, and between the cell element separation film 105 and the cell conductive line 140.

Although the cell insulating film 130 may be a single film, as shown, the cell insulating film 130 may be a multi-layer film including a first cell insulating film 131 and a second cell insulating film 132. For example, the first cell insulating film 131 may include a silicon oxide film, and the second cell insulating film 132 may include, but is not limited to, a silicon nitride film. Unlike the shown example, it goes without saying that the cell insulating film 130 may include three or more insulating films. When the cell insulating film 130 includes a third cell insulating film, the third cell insulating film may be a silicon oxide film.

In the cross-sectional view such as FIG. 4, the upper side 100US of the substrate 100 may be defined at the boundary between the cell insulating film 130 and the substrate 100.

The cell line spacer 150 may be disposed on the side walls of the cell conductive line 140 and the cell line capping film 144. The cell line spacer 150 may be disposed on the substrate 100 and the cell element separation film 105 at a portion of the cell conductive line 140 in which the bit line contact 146 is disposed. The cell line spacer 150 may be disposed on the side walls of the cell conductive line 140, the cell line capping film 144, and the bit line contact 146.

In the remaining portion of the cell conductive line 140 in which the bit line contact 146 is not formed, the cell line spacer 150 may be disposed on the cell insulating film 130. The cell line spacer 150 may be disposed on the side walls of the cell conductive line 140 and the cell line capping film 144.

The cell line spacer 150 may be disposed on the long side wall of the bit line structure 140ST that extends long in the second direction D2.

Although the cell line spacer 150 may be a single film, as shown, the cell line spacer 150 may be a multi-layer film including first to fourth cell line spacers 151, 152, 153, and 154. For example, the first to fourth cell line spacers 151, 152, 153, and 154 may include, but are not limited to, one of a silicon oxide film, a silicon nitride film, a silicon oxynitride film (SiON), a silicon oxycarbonitride film (SiOCN), air, and combinations thereof. For example, the second cell line spacer 152 may not be disposed on the cell conductive film 130, but may be disposed on a side wall of the bit line contact 146.

A fence pattern 170 may be disposed on the substrate 100 and the cell element separation film 105. The fence pattern 170 may be formed to overlap the cell gate structure 110 formed inside the substrate 100 and the cell element separation film 105. The fence pattern 170 may be disposed between the bit line structures 140ST extending in the second direction D2. The fence pattern 170 may include, for example, at least one of silicon oxide, silicon nitride, silicon oxynitride, and combinations thereof.

The plurality of storage contacts 120 may be disposed between the cell conductive lines 140 adjacent in the first direction D1. The storage contact 120 may be disposed between the fence patterns 170 adjacent to each other in the second direction D2. The storage contact 120 may overlap the substrate 100 and the cell element separation film 105 between adjacent cell conductive lines 140. The storage contact 120 may be connected to the active region ACT. The storage contact 120 may be connected to the storage connecting region 103b of the cell active region ACT. Here, the storage contact 120 may correspond to the buried contact BC.

The storage contact 120 may include, for example, at least one of a semiconductor material doped with impurity, a conductive silicide compound, a conductive metal nitride, and a metal.

A plurality of storage pad structures 160ST may be disposed on the storage contacts 120. The storage pad structures 160ST may be electrically connected to the storage contacts 120. Here, the storage pad structures 160ST may correspond to the landing pads LP.

The storage pad structures 160ST may include a first storage pad 160 disposed on the storage contacts 120, and a second storage pad 165 on the first storage pad 160. The second storage pad 165 may be disposed between the first storage pad 160 and the data storage pattern 190.

The storage pad structure 160ST may overlap a part of an upper side of the bit line structure 140ST. For example, the storage pad structures 160ST may overlap an upper side 144US of the cell line capping film in a thickness direction of the substrate 100.

The first storage pad 160 may include a first silicide film 161 and a first conductive film 162. The first silicide film 161 may be disposed between the storage contact 120 and the first conductive film 162. The first silicide film 161 may be connected to the storage contact 120. The first silicide film 161 may include a metal silicide compound. The first silicide film 161 may include, for example, but is not limited to, at least one of cobalt (Co), titanium (Ti) and/or nickel (Ni).

An upper side 162US of the first conductive film may be disposed on the same plane as an upper side 144US of the cell line capping film. The thickness T1 of the first conductive film 162 may be different from the thickness T2 of the second storage pad 165 in the fourth direction D4. For example, the thickness T1 of the first conductive film 162 may be greater than the thickness T2 of the second storage pad 165 in the fourth direction D4.

The first conductive film 162 and the second storage pad 165 may include a conductive material. The first conductive film 162 may include, for example, at least one of a conductive silicide compound, a conductive metal nitride, a conductive metal carbide, a conductive metal oxide, and a conductive metal carbonitride. The first conductive film 162 may include, but is not limited to, titanium nitride (TiN). The second storage pad 165 may include a metal. For example, the second storage pad 165 may be formed of a metal. The second storage pad 165 may include, but is not limited to, tungsten (W).

A pad separation pattern 180 may be formed on the storage pad structure 160ST and the bit line structure 140ST. For example, the pad separation pattern 180 may be disposed on the cell line capping film 144.

The pad separation pattern 180 may define a region of the storage pad structure 160ST that forms a plurality of isolated regions. The pad separation pattern 180 may separate the adjacent storage pad structures 160ST.

The pad separation pattern 180 does not cover an upper side of the storage pad structure 160ST. The pad separation pattern 180 may be disposed on the same plane as the upper side of the storage pad structure 160ST.

The pad separation pattern 180 includes an insulating material. The pad separation pattern 180 may electrically separate the plurality of storage pad structures 160ST from each other. For example, the pad separation pattern 180 may include at least one of a silicon oxide film, a silicon nitride film, a silicon oxynitride film, a silicon oxycarbonitride film, and a silicon carbonitride film.

An upper etching stop film 297 may be disposed on the pad separation pattern 180 and the storage pad structure 160ST. The upper etching stop film 292 may extend up to the peri region 24 as well as the cell region 20. The upper etching stop film 297 may include, for example, but is not limited to, at least one of a silicon nitride film, a silicon carbonitride film, a silicon boron nitride film (SiBN), a silicon oxynitride film, and a silicon oxycarbide film.

The data storage pattern 190 may be disposed on the storage pad structure 160ST. The data storage pattern 190 may be electrically connected to the storage pad structure 160ST.

A part of the data storage pattern 190 may be disposed inside the upper etching stop film 297. The data storage pattern 190 may include, for example, but is not limited to, a capacitor. The data storage pattern 190 includes a lower electrode 191, a capacitor dielectric film 192, and an upper electrode 193.

The lower electrode 191 may be disposed on the storage pad structure 160ST. The lower electrode 191 may be in contact with the second storage pad 165. The lower electrode 191 is shown to have a pillar shape, but is not limited thereto. The lower electrode 191 may, of course, have a cylindrical shape.

The capacitor dielectric film 192 is disposed on the lower electrode 191. The capacitor dielectric film 192 may be formed along the profile of the lower electrode 191. The upper electrode 193 is disposed on the capacitor dielectric film 192. The upper electrode 193 may cover an outer wall of the lower electrode 191.

For example, the capacitor dielectric film 192 may be disposed in a portion that vertically overlaps the upper electrode 193. The capacitor dielectric film 192 may not extend up to the peri region 24.

Each of the lower electrode 191 and the upper electrode 193 may include, but are not limited to, a doped semiconductor material, a conductive metal nitride (e.g., titanium nitride, tantalum nitride, niobium nitride or tungsten nitride), or a metal (e.g., ruthenium, iridium, titanium, tantalum or niobium oxide).

For example, the capacitor dielectric film 192 may include at least one of a ferroelectric material, an antiferroelectric material, and a paraelectric material. For example, the capacitor dielectric film 192 may include one of the ferroelectric material, the antiferroelectric material, the paraelectric material, combinations of the ferroelectric material and the antiferroelectric material, combinations of the ferroelectric material and the paraelectric material, combinations of the paraelectric material and the antiferroelectric material, and combinations of the ferroelectric material, the antiferroelectric material and the paraelectric material.

As an example, the capacitor dielectric film 192 may include a stacked film structure in which zirconium oxide, aluminum oxide, and zirconium oxide are stacked in sequence. As another example, the capacitor dielectric film 192 may include a dielectric film containing hafnium (Hf). The above-mentioned contents regarding the material of the capacitor dielectric film 192 are merely exemplary, and the technical idea of the present disclosure is not limited thereto.

Unlike the above contents, the data storage patterns 190 may be variable resistance patterns that may be switched into two resistance statuses by electrical pulses applied to the memory element. For example, the data storage patterns 190 may include a phase-change material whose crystal status changes depending on the amount of current, perovskite compounds, transition metal oxide, magnetic materials, ferromagnetic materials or antiferromagnetic materials.

A peri element separation film 26 may be formed inside the substrate 100 of the peri region 24. The peri element separation film 26 may define a peri active region inside the peri region 24. An upper side of the peri element separation film 26 is shown to be coplanar with the upper side 100US of the substrate, but the embodiment is not limited thereto. The peri element separation film 26 may include, for example, but is not limited to, at least one of a silicon oxide film, a silicon nitride film, and a silicon oxynitride film.

The peri gate structure 240ST may be disposed on the substrate 100 of the peri region 24. The peri gate structure 240ST may be disposed on a peri active region defined by the peri element separation film 26.

The peri gate structure 240ST may include a peri gate insulating film 230, a peri gate conductive film 240, and a peri capping film 244, which are sequentially stacked on the substrate 100. The peri gate structure 240ST may include a peri spacer 245 which is disposed on the side wall of the peri gate conductive film 240 and the side wall of the peri capping film 244.

The peri gate conductive film 240 may include first to third peri conductive films 241, 242, and 243 which are sequentially stacked on the peri gate insulating film 230. As an example, an additional conductive film may not be disposed between the peri gate conductive film 240 and the peri gate insulating film 230. As another example, unlike the shown example, an additional conductive film, such as a work function conductive film, may be disposed between the peri gate conductive film 240 and the peri gate insulating film 230.

Although the two peri gate structures 240ST are shown to be disposed between adjacent peri element separation films 26, this is only for convenience of explanation and the embodiment is not limited thereto.

For example, the peri gate conductive film 240 may have the same stack structure as the cell conductive line 140. The thickness of the peri gate conductive film 240 may be the same as the thickness of the cell conductive line 140.

The first peri conductive film 241 may include the same material as the first cell conductive film 141. The second peri conductive film 242 may include the same material as the second cell conductive film 142. The third peri conductive film 243 may include the same material as the third cell conductive film 143.

The peri gate insulating film 230 may include, for example, silicon oxide, silicon nitride, silicon oxynitride, or a high dielectric constant material having a higher dielectric constant than silicon oxide.

The peri spacer 245 may include, for example, at least one of silicon nitride, silicon oxynitride, silicon oxide, silicon carbonitride, silicon oxycarbonitride and combinations thereof. Although the peri spacer 245 is shown as being a single layer, this is only for convenience of explanation and the embodiment is not limited thereto. It goes without saying that the peri spacer 245 may be a multi-layer film.

The peri capping film 244 may include, for example, at least one of a silicon nitride film, a silicon oxynitride, and a silicon oxide. Also, the upper side of the peri capping film 244 may be lower than the upper side 144US of the cell line capping film on the basis of the upper side 100US of the substrate.

A lower etching stop film 250 may be disposed on the substrate 100. The lower etching stop film 250 may be formed along the profile of the peri gate structure 240ST. The lower etching stop film 250 may include, for example, at least one of a silicon nitride film, a silicon oxynitride, a silicon carbonitride, and a silicon oxycarbonitride.

A first peri interlayer insulating film 290 may be disposed on the lower etching stop film 250. The first peri interlayer insulating film 290 may be disposed around the peri gate structure 240ST. For example, the first peri interlayer insulating film 290 may include a silicon oxide-based insulating material. The first peri interlayer insulating film 290 may include, but is not limited to, silicon oxide.

An inserting interlayer insulating film 291 is disposed on the peri gate structure 240ST and the first peri interlayer insulating film 290. The inserting interlayer insulating film 291 may cover the peri gate structure 240ST and the first peri interlayer insulating film 290. The inserting interlayer insulating film 291 may cover the lower etching stop film 250 that protrudes above the upper side of the first peri interlayer insulating film 290.

The inserting interlayer insulating film 291 may include a material different from the first peri interlayer insulating film 290. The inserting interlayer insulating film 291 may include, for example, a silicon nitride-based insulating material. For example, the inserting interlayer insulating film 291 may include silicon nitride.

The peri contact plugs 260 may be disposed on both sides of the peri gate structure 240ST. The peri contact plug 260 penetrates the inserting interlayer insulating film 291 and the first peri interlayer insulating film 290, and may extend up to the substrate 100 of the peri region 24.

The peri contact plug 260 may include a recess 260R, a second silicide film 261, a second conductive film 262, and a third conductive film 263. The recess 260R may extend into the substrate 100 in a fourth direction D4. A bottom side of the recess 260R may expose at least a part of the substrate 100.

The second silicide film 261 may be disposed on a bottom side of the recess 260R. The second silicide film 261 may be disposed in the substrate 100. The second silicide film 261 may include a metal silicide compound. The second silicide film 261 may include, for example, but is not limited to, at least one of cobalt (Co), titanium (Ti), and/or nickel (Ni).

The second conductive film 262 may be disposed on the second silicide film 261. The second conductive film 262 may extend in the fourth direction D4 along the side wall of the recess 260R. The second conductive film 262 may be disposed on the upper side 100US of the substrate. The second conductive film 262 may extend by a first length T3a in the fourth direction D4 along the side wall of the recess 260R. The second conductive film 262 may be formed on the side wall of the recess 260R at a thickness of a second length T3b in the first direction D1. The length T3b of the second conductive film 262 in the first direction D1 may be smaller than the length W1 of the first conductive film 162 in the first direction D1.

The third conductive film 263 may be disposed on the second conductive film 262. The third conductive film 263 may fill the inside of the recess 260R. The upper side 262US of the second conductive film and the upper side 263US of the third conductive film may be located at the same level in the fourth direction D4.

The second conductive film 262 and the third conductive film 263 may include a conductive material. The second conductive film 262 may include, for example, at least one of a conductive silicide compound, a conductive metal nitride, a conductive metal carbide, a conductive metal oxide, and a conductive metal carbonitride. The second conductive film 262 may include, for example, but is not limited to, titanium nitride (TiN). The third conductive film 263 may include a metal. For example, the third conductive film 263 may be formed of a metal. The third conductive film 263 may include, for example, but is not limited to, tungsten (W).

The peri wiring lines 265 may be disposed on the inserting interlayer insulating film 291. The peri wiring line 265 may be disposed on the peri gate structure 240ST. The peri wiring line 265 may be connected to the peri contact plug 260. From the viewpoint of a cross-sectional view, when the peri wiring line 265 is connected to the peri contact plug 260, the peri wiring line 265 may be a portion disposed on the inserting interlayer insulating film 291. The peri wiring lines 265 may be disposed on the upper side 291US of the inserting interlayer insulating film.

The peri wiring line 265 may be directly connected to the peri contact plug 260. The peri wiring line 265 may be directly connected to the second conductive film 262 and the third conductive film 263.

The peri wiring line 265 may include the same material as the third conductive film 263. The peri wiring line 265 may include, for example, at least one of a conductive silicide compound, a conductive metal nitride, a conductive metal carbide, a conductive metal oxide, and a conductive metal carbonitride. For example, the peri wiring line 265 may be formed of a metal. The peri wiring line 265 may include, for example, but is not limited to, tungsten (W).

The peri wiring separation pattern 280 may separate adjacent peri wiring lines 265. The upper side of the peri wiring separation pattern 280 may be located on the same plane as the upper side 265US of the peri wiring line. The peri wiring separation pattern 280 may be in contact with the side wall of the peri wiring line 265. The peri wiring separation pattern 280 includes an insulating material. The peri wiring separation pattern 280 may electrically separate adjacent peri wiring lines 265 from each other. For example, the peri wiring separation pattern 280 may include at least one of a silicon oxide film, a silicon nitride film, a silicon oxynitride film, a silicon oxycarbonitride film, and a silicon carbonitride film.

The upper etching stop film 297 may be disposed on the peri wiring separation pattern 280. The upper etching stop film 297 is not in contact with the side wall of the peri wiring line 265.

A second peri interlayer insulating film 293 may be disposed on the upper etching stop film 297. Although not shown, the second peri interlayer insulating film 293 may cover the side wall of the upper electrode 193. The second peri interlayer insulating film 293 may include an insulating material.

In the first direction D1, a width W1 of the first conductive film 162 on the first silicide film 161 may be different from a width W2 of the second conductive film 262 on the second silicide film 261. The width W1 of the first conductive film 162 that is in contact with the first silicide film 161 may be different from the width W2 of the second conductive film 262 that is in contact with the second silicide film 261. For example, in the first direction D1, the width W1 of the first conductive film 162 on the first silicide film 161 may be larger than the width W2 of the second conductive film 262 on the second silicide film 261.

In the fourth direction D4, an upper side 165US of the second storage pad may be located at the same level as an upper side 265US of the peri wiring line. In the fourth direction D4, a lower side 165BS of the second storage pad may be located at the same level as a lower side 265BS of the peri wiring line.

In the fourth direction D4, the upper side 162US of the first conductive film may be located at the same level as the upper side 262US of the second conductive film. In the fourth direction D4, the upper side 144US of the bit line structure may be located at the same level as the upper side 291US of the inserting interlayer insulating film.

In the fourth direction D4, the thickness T1 of the first conductive film 162 from the first silicide film 161 may be different from a thickness T3a of the second conductive film 262 from the second silicide film 261. For example, in the fourth direction D4, the thickness T1 of the first silicide film 161 from the first conductive film 162 may be smaller than the thickness T3a of the second silicide film 261 from the second conductive film 262. The thickness T1 of the first conductive film 162 from the upper side of the first silicide film 161 may be different from the thickness T3a of the second conductive film 262 from the upper side of the second silicide film 261. In the fourth direction D4, the thickness T1 of the first conductive film 162 from the first silicide film 161 to the lower side 165BS of the second storage pad 165 may be different from the thickness T3a of the second conductive film 262 from the second silicide film 261 to the lower side 265BS of the peri wiring line 265.

The thickness T2 of the second storage pad 165 may be equal to a thickness T5 of the peri wiring line 265 in the fourth direction D4. The thickness T4 of the third conductive film 263 may be different from the thickness T1 of the first conductive film 162 in the fourth direction D4. For example, the thickness T4 of the third conductive film 263 may be greater than the thickness T1 of the first conductive film 162 in the fourth direction D4.

The first silicide film 161 and the second silicide film 261 may be located at different levels from each other in the fourth direction D4. For example, the first silicide film 161 may be disposed on the upper side 100US of the substrate, and the second silicide film 261 may be disposed below the upper side 100US of the substrate.

The first conductive film 162 and the second conductive film 262 may include the same metal material. For example, each of the first conductive film 162 and the second conductive film 262 may include titanium nitride (TiN). The second storage pad 165, the third conductive film 263, and the peri wiring line 265 may include the same metal material. For example, the second storage pad 165, the third conductive film 263, and the peri wiring line 265 may each include tungsten (W). The first conductive film 162 and the third conductive film 263 may include different metal materials from each other. For example, the first conductive film 162 may include titanium nitride (TiN), and the third conductive film 263 may include tungsten (W).

In the semiconductor memory device according to some embodiments, the first conductive film 162 may be formed of a single titanium nitride (TiN) layer, and the second storage pad 165 may be formed of a single tungsten (W) layer.

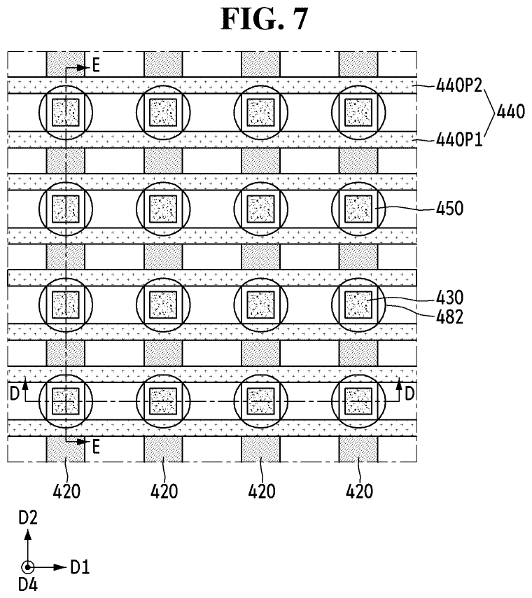

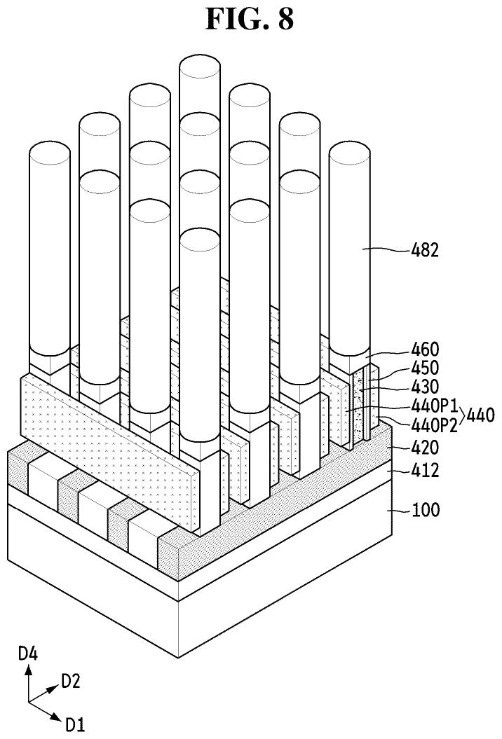

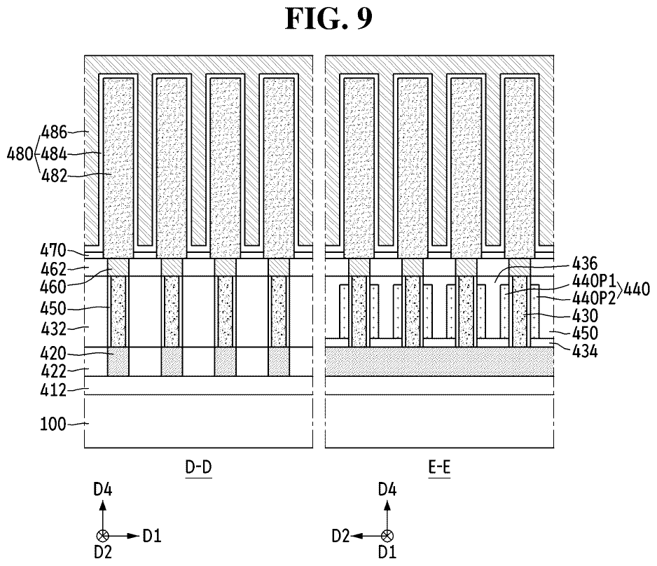

FIG. 7 is a layout diagram for explaining a semiconductor memory device according to some embodiments. FIG. 8 is a perspective view for explaining a semiconductor memory device according to some embodiments. FIG. 9 is a cross-sectional view taken along lines D-D and E-E of FIG. 7.

For reference, FIG. 7 may be an enlarged view of the cell region 20 of FIG. 1.

With reference to FIGS. 7 to 9, the semiconductor memory device according to some embodiments may include a substrate 100, a plurality of first conductive lines 420, a channel layer 430, a gate electrode 440, a gate insulating film 450, and a capacitor 480.

The semiconductor memory device according to some embodiments may be a memory device including a vertical channel transistor (VCT). The vertical channel transistor may refer to a structure in which a channel length of the channel layer 430 extends from the substrate 100 along the vertical direction.

A lower insulating layer 412 may be disposed on the substrate 100. A plurality of first conductive lines 420 may be spaced apart from each other in the first direction D1 and extend in the second direction D2 on the lower insulating layer 412. A plurality of first insulating patterns 422 may be disposed on the lower insulating layer 412 to fill spaces between the plurality of first conductive lines 420. The plurality of first insulating patterns 422 may extend in the second direction D2. The upper sides of the plurality of first insulating patterns 422 may be disposed at the same level as the upper sides of the plurality of first conductive lines 420. The plurality of first conductive lines 420 may function as bit lines.

The plurality of first conductive lines 420 may include a doped semiconductor material, a metal, a conductive metal nitride, a conductive metal silicide, a conductive metal oxide, or a combination thereof. For example, the plurality of first conductive lines 420 may be made up of, but are not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof. The plurality of first conductive lines 420 may include a single layer or multiple layers of the above materials. In the exemplary embodiments, the plurality of first conductive lines 420 may include graphene, carbon nanotube or a combination thereof.

A channel layers 430 may be arranged in the form of a matrix in which they are disposed on the plurality of first conductive lines 420 to be spaced apart from each other in the first direction D1 and the second direction D2. The channel layer 430 may have a first width along the first direction D1 and a first height along the fourth direction D4, and the first height may be greater than the first width. Here, the fourth direction D4 intersects the first direction D1 and the second direction D2, and may be, for example, a direction perpendicular to the upper side of the substrate 100. For example, the first height may be, but not limited to, about 2 to 10 times the first width. A bottom portion of the channel layer 430 may function as a third source/drain region (not shown), an upper portion of the channel layer 430 may function as a fourth source/drain region (not shown), and a part of the channel layer 430 between the third and fourth source/drain regions may function as a channel region (not shown).

As an example, the channel layer 430 may include an oxide semiconductor, and the oxide semiconductor may include, for example, InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, InxGayO or combinations thereof. The channel layer 430 may include a single layer or multi-layers of the oxide semiconductor. In some embodiments, the channel layer 430 may have a bandgap energy that is greater than the bandgap energy of silicon. For example, the channel layer 430 may have a bandgap energy of about 1.5 eV to 5.6 eV. For example, the channel layer 430 may have optimum channel performance when having the bandgap energy of about 2.0 eV to 4.0 eV. For example, the channel layer 430 may be, but is not limited to, polycrystalline or amorphous. As another example, the channel layer 430 may include graphene, carbon nanotubes, or a combination thereof. As yet another example, the channel layer 430 may include a silicon-based semiconductor material. The channel layer 430 may include a single crystal semiconductor material, for example, but not limited to, single crystal silicon or single crystal silicon-germanium The gate electrode 440 may extend in the first direction D1 on both side walls of the channel layer 430. The gate electrode 440 may include a first sub-gate electrode 440P1 that faces a first side wall of the channel layer 430, and a second sub-gate electrode 440P2 that faces a second side wall opposite to the first side wall of the channel layer 430. As the single channel layer 430 is disposed between the first sub-gate electrode 440P1 and the second sub-gate electrode 440P2, the semiconductor device may have a dual gate transistor structure. However, the technical idea of the present disclosure is not limited thereto, the second sub-gate electrode 440P2 is omitted, and only the first sub-gate electrode 440P1 that faces the first side wall of the channel layer 430 may be formed to realize a single gate transistor structure. The materials included in the gate electrode 440 may be the same as description of the cell gate electrode 112.

The gate insulating film 450 surrounds the side walls of the channel layer 430, and may be interposed between the channel layer 430 and the gate electrode 440. For example, as shown in FIG. 9, the entire side walls of the channel layer 430 may be surrounded by the gate insulating film 450, and a part of the side walls of the gate electrode 440 may be in contact with the gate insulating film 450. In other embodiments, the gate insulating film 450 extends in the extending direction (i.e., the first direction D1) of the gate electrode 440, and only the two side walls that face the gate electrode 440 among the side walls of the channel layer 430 may be in contact with the gate insulating film 450. In the exemplary embodiments, the gate insulating film 450 may be made up of a silicon oxide film, a silicon oxynitride film, a high dielectric constant material having a higher dielectric constant than the silicon oxide film, or a combination thereof.

A plurality of second insulating patterns 432 may extend along the second direction D2 on the plurality of first insulating patterns 422. The channel layer 430 may be disposed between two adjacent second insulating patterns 432 among the plurality of second insulating patterns 432. Further, a first buried layer 434 and a second buried layer 436 may be disposed in a space between two adjacent channel layers 430, between two adjacent second insulating patterns 432. The first buried layer 434 may be disposed at the bottom portion of the space between two adjacent channel layers 430. The second buried layer 436 may be formed to fill the remainder of the space between two adjacent channel layers 430 on the first buried layer 434. The upper face of the second buried layer 436 may be disposed at the same level as the upper face of the channel layer 430, and the second buried layer 436 may cover the upper face of the gate electrode 440. In contrast, the plurality of second insulating patterns 432 may be formed of a continuous material layer with the plurality of first insulating patterns 422, or the second buried layer 436 may be formed of a continuous material layer with the first buried layer 434.

Capacitor contacts 460 may be disposed on the channel layer 430. The capacitor contacts 460 are disposed to vertically overlap the channel layer 430, and may be arranged in the form of a matrix in which they are spaced apart from each other in the first direction D1 and the second direction D2. The capacitor contacts 460 may be made up of, but are not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx or a combination thereof. An upper insulating film 462 may surround the side walls of the capacitor contacts 460 on the plurality of second insulating patterns 432 and the second buried layer 436.

An etching stop film 470 may be disposed on the upper insulating layer 462. A capacitor 480 may be disposed on the etching stop film 470. The capacitor 480 may include a second lower electrode 482, a second capacitor dielectric film 484, and a second upper electrode 486. The second lower electrode 482 penetrates the etching stop film 470, and may be electrically connected to the upper side of the capacitor contact 460. The second lower electrode 482 may be formed in a pillar type extending in a fourth direction D4, but is not limited thereto. In the exemplary embodiments, the second lower electrodes 482 may be disposed to vertically overlap the capacitor contacts 460, and may be arranged in the form of a matrix in which they are spaced apart from each other in the first direction D1 and the second direction D2. Alternatively, a landing pad (not shown) may be further disposed between the capacitor contact 460 and the second lower electrode 482, and the second lower electrode 482 may be arranged in a hexagonal shape.

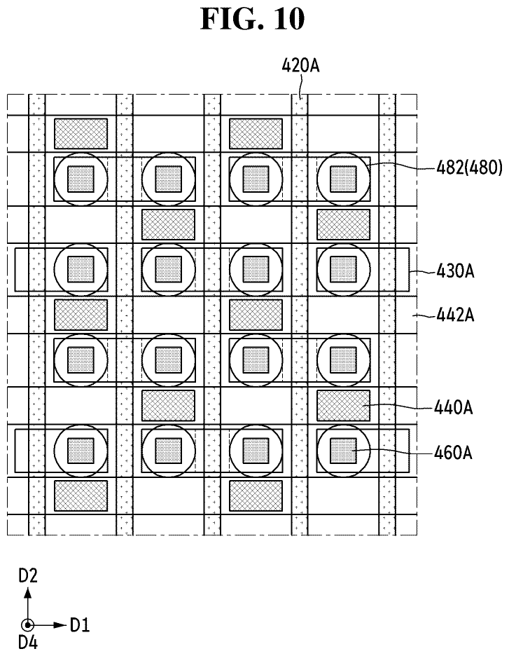

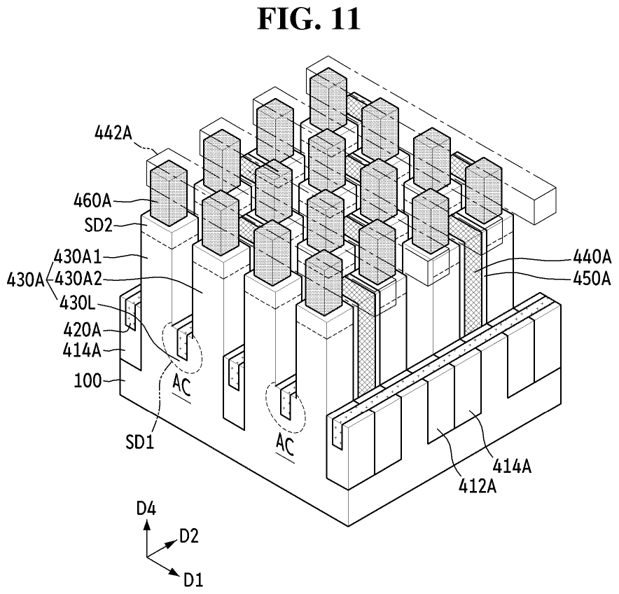

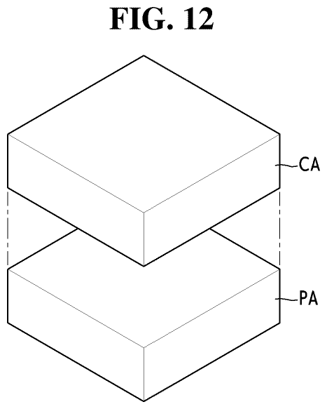

FIG. 10 is a layout diagram for explaining a semiconductor memory device according to some embodiments. FIG. 11 is a perspective view for explaining the semiconductor memory device according to some embodiments. FIG. 12 is a diagram for explaining the semiconductor memory device according to some embodiments.

Referring to FIGS. 10 and 11, the semiconductor memory device according to some embodiments may include a substrate 100, a plurality of first conductive lines 420A, a channel structure 430A, a contact gate electrode 440A, a plurality of second conductive lines 442A, and a capacitor 480. The semiconductor memory device according to some embodiments may be a memory device including a vertical channel transistor (VCT).

A plurality of active regions AC may be defined in the substrate 100 by a first element separation pattern 412A and a second element separation pattern 414A. A channel structure 430A may be disposed in each active region AC. The channel structure 430A may include a first active pillar 430A1 and a second active pillar 430A2 which each extend in a vertical direction, and a connecting portion 430L connected to the bottom portion of the first active pillar 430A1 and the bottom portion of the second active pillar 430A2. A first source/drain region SD1 may be disposed in the connecting portion 430L. A second source/drain region SD2 may be disposed on the upper sides of the first and second active pillars 430A1 and 430A2. Each of the first active pillar 430A1 and the second active pillar 430A2 may constitute an independent unit memory cell.

The plurality of first conductive lines 420A may extend in a direction that intersects each of the plurality of active regions AC, and may extend, for example, in the second direction D2. One of the plurality of first conductive lines 420A may be disposed on the connecting portion 430L between the first active pillar 430A1 and the second active pillar 430A 2. One first conductive line 420A may be disposed on the first source/drain region SD1. The other first conductive line 420A adjacent to one first conductive line 420A may be disposed between the two channel structures 430A. One of the plurality of first conductive lines 420A may function as a common bit line included in the two unit memory cells constituted by the first active pillar 430A1 and the second active pillar 430A2 disposed on either side of the one first conductive line 420A.

A single contact gate electrode 440A may be disposed between two channel structures 430A adjacent to each other in the second direction D2. For example, the contact gate electrode 440A may be disposed between the first active pillar 430A1 included in one channel structure 430A and the second active pillar 430A2 of the channel structure 430A adjacent thereto. The single contact gate electrode 440A may be shared by the first active pillar 430A1 and the second active pillar 430A2 disposed on both side walls of the contact gate electrode 440A. A gate insulating film 450A may be disposed between the contact gate electrode 440A and the first active pillar 430A1, and between the contact gate electrode 440A and the second active pillar 430A2. A plurality of second conductive lines 442A may extend in the first direction D1 on the upper side of the contact gate electrode 440A. The plurality of second conductive lines 442A may function as word lines of the semiconductor device.

A capacitor contact 460A may be disposed on the channel structure 430A. The capacitor contact 460A may be disposed on the second source/drain region SD2, and the capacitor 480 may be disposed on the capacitor contact 460A.

Referring to FIG. 12, the semiconductor memory device according to some embodiments may have a cell on peri (COP) structure in which a cell array region CA is disposed on a peri structure region PA.

The peri structure region PA may correspond to the peri region 24 of FIGS. 1 and 5. The cell array region CA may include the vertical channel transistor VCT of FIGS. 7 to 11.

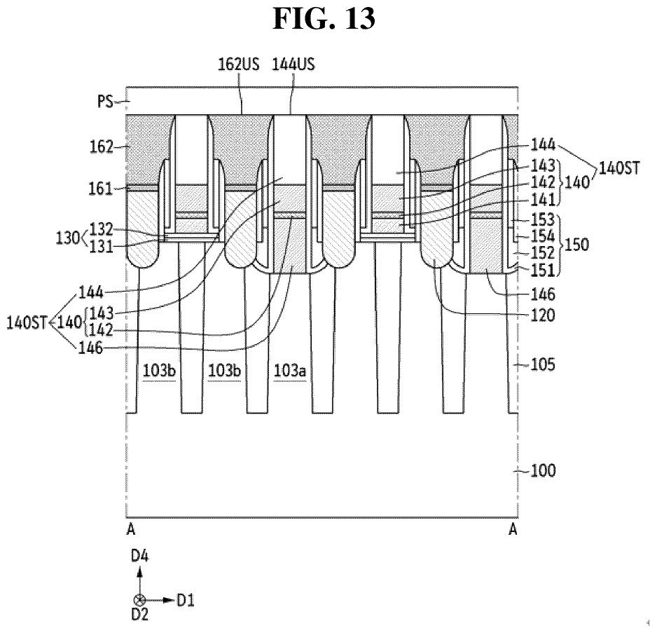

FIGS. 13 to 20 are intermediate step diagrams for explaining a method for fabricating a semiconductor memory device according to some embodiments. Among the explanations of the fabricating method, repeated parts of contents explained using FIGS. 1 to 6 will be briefly explained or omitted.

Referring to FIGS. 1 and 13, a substrate 100 including the cell region (20 of FIG. 1), the peri region (24 of FIG. 1), and the cell region separation film (22 of FIG. 1) is provided.

A cell active region (ACT of FIG. 2) defined by the cell element separation film 105 may be formed in the substrate 100 of the cell region (20 of FIG. 1). The cell active region (ACT of FIG. 2) may include a bit line connecting region 103a and a storage connecting region 103b. The cell element separation film 105 may include an insulating material and have an STI structure.

A pre-cell insulating film (not shown), a pre-cell conductive line (not shown), a pre-bit line contact (not shown), and a pre-cell line capping film (not shown) may be formed on the substrate 100 of the cell region (20 of FIG. 1). The pre-cell insulating film (not shown) may include the same material as the cell insulating film 130 described above, the pre-cell conductive line (not shown) may include the same material as the cell conductive line 140, the pre-bit line contact (not shown) may include the same material as the bit line contact 146, and the pre-cell line capping film (not shown) may include the same material as the cell line capping film 144, respectively.

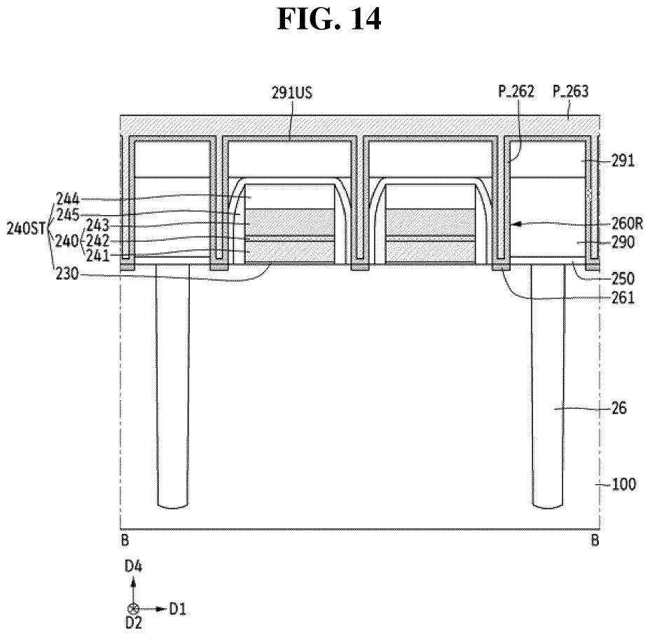

Referring to FIG. 14, the peri gate structure 240ST may be formed on the substrate 100 of the peri region (24 of FIG. 1). The peri gate structure 240ST may include a peri gate insulating film 230, a peri gate conductive film 240, a peri capping film 244, and a peri spacer 245.

A lower etching stop film 250 may be formed on the substrate 100. The lower etching stop film 250 may be formed on the peri gate structure 240ST. The lower etching stop film 250 may be formed along the profile of the peri gate structure 240ST.

The first peri interlayer insulating film 290 may be formed on the lower etching stop film 250. The first peri interlayer insulating film 290 may entirely cover the lower etching stop film 250. The first peri interlayer insulating film 290 may include, for example, a silicon oxide-based insulating material.

The inserting interlayer insulating film 291 may be formed on the first peri interlayer insulating film 290. The inserting interlayer insulating layer 291 may be formed on the lower etching stop film 250.

Referring again to FIG. 13, a bit line structure 140ST extending long in the second direction D2 may be formed on the cell region (20 of FIG. 1). The cell line spacer 150 may be formed on a side wall of the bit line structure 140ST. A fence pattern (170 of FIG. 6) may be formed between the bit line structures 140ST adjacent in the first direction D1. After forming the fence pattern 170, the storage contact 120 may be formed between adjacent cell conductive lines 140 and between the fence patterns 170 adjacent in the second direction D2.

The storage contact 120 may be formed between a plurality of bit line structures 140ST. The storage contact 120 may be connected to the storage connecting region 103b of the cell active region (ACT of FIG. 2). The storage contact 120 may overlap the substrate 100 and the cell element separation film 105 between adjacent cell conductive lines 140. The storage contact 120 may include, for example, but is not limited to, at least one of a semiconductor material doped with impurity, a conductive silicide compound, a conductive metal nitride, and a metal.

The first silicide film 161, and the first conductive film 162 on the first silicide film 161 may be sequentially formed on the storage contact 120.

Although not specifically shown, a first silicide metal layer (not shown) may be deposited on the storage contact 120. The first silicide metal layer (not shown) may include, for example, but is not limited to at least one of cobalt (Co), titanium (Ti), and/or nickel (Ni). A silicide process may be performed on the first silicide metal layer (not shown). For example, annealing may be performed on the first silicide metal layer (not shown). Accordingly, the first silicide film 161 including a metal silicide compound may be formed.

The first conductive film 162 may be formed between the plurality of bit line structures 140ST on the first silicide film 161. The first conductive film 162 may be formed on at least a part of the side walls of the plurality of bit line structures 140ST. The first conductive film 162 may include, but is not limited to, titanium nitride (TiN).

After that, a chemical mechanical polishing (CMP) and/or an etch-back process may be performed on the first conductive film 162 and the bit line structures 140ST. The upper side 162US of the first conductive film may be coplanar with the upper side 144US of the bit line structures 140ST. The upper side 162US of the first conductive film, the upper side 144US of the bit line structure 140ST, and the upper side 291US of the inserting interlayer insulating film may be coplanar.

Although not specifically shown, the first silicide film 161 and the first conductive film 162 formed in the peri region (24 of FIG. 1) may be removed using a chemical mechanical polishing (CMP) and/or an etch-back process.

After that, a cell protective film PS may be formed on the first conductive film 162. The cell protective film PS may be formed on the cell region 20, but may not be formed on the peri region 24. The cell protective film PS may cover the upper side 162US of the first conductive film and the upper side 144US of the bit line structure 140ST. The cell protective film PS may include a nitride-based material. The cell protective film PS may include, but is not limited to, silicon nitride. The cell protective film PS may protect the cell region (20 of FIG. 1) when forming the peri contact plug 260 of the peri region (24 of FIG. 1) to be described later. As an example, the cell protective film PS may be formed on the first conductive film 162, using a deposition process.

After that, referring again to FIG. 14, a recess 260R may be formed in the inserting interlayer insulating film 291 and the first peri interlayer insulating film 290. The recess 260R may penetrate the inserting interlayer insulating film 291 and the first peri interlayer insulating film 290. The recess 260R may extend into the substrate 100 on both sides of the peri gate structure 240ST. The recess 260R may expose the substrate 100 of the peri region (24 of FIG. 1).

After that, a second silicide film 261 is formed on the bottom side of the recess 260R, and a pre-second conductive film P_262 that extends along the side wall of the recess 260R may be formed on the second silicide film 261.

Although not specifically shown, a second silicide metal layer (not shown) may be deposited on the substrate 100. The second silicide metal layer (not shown) may include, for example, but is not limited to, at least one of cobalt (Co), titanium (Ti) and/or nickel (Ni). A silicide process may be performed on the second silicide metal layer (not shown). For example, annealing may be performed on the second silicide metal layer (not shown). Accordingly, a second silicide film 261 including a metal silicide compound may be formed.

The pre-second conductive film P_262 may extend in the fourth direction D4 along the upper side of the second silicide film 261 and the side wall of the recess 260R. The pre-second conductive film P_262 may extend along the exposed upper side 291US of the inserting interlayer insulating film. The pre-second conductive film P_262 may include, but is not limited to, titanium nitride (TiN).

After that, a pre-third conductive film P_263 that fills the inside of the recess 260R may be formed on the pre-second conductive film P_262. The pre-third conductive film P_263 may include, for example, but is not limited to, tungsten (W).

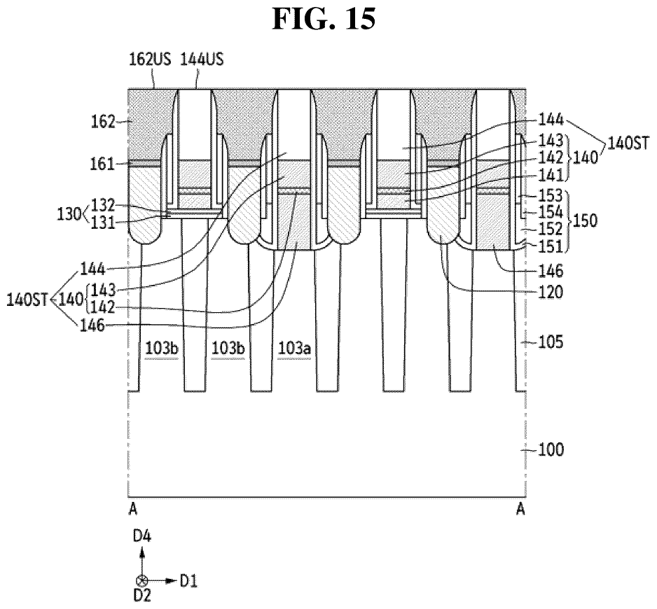

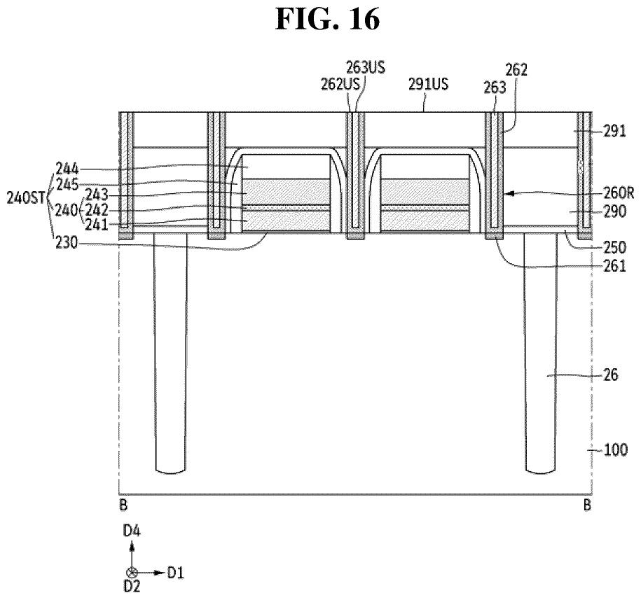

After that, referring to FIGS. 15 and 16, the cell protective film PS may be removed using a chemical mechanical polishing (CMP) and/or an etch-back process, and the upper side 162US of the first conductive film and the upper side 144US of the bit line structure may be exposed. The pre-second conductive film (P_262 of FIG. 14) and the pre-third conductive film (P_263 of FIG. 14) on the upper side 291US of the inserting interlayer insulating film may be removed, using a chemical mechanical polishing (CMP) and/or an etch-back process. The upper side 162US of the first conductive film, the upper side 262US of the second conductive film, and the upper side 263US of the third conductive film may be located on the same plane. The upper side 144US of the bit line structure and the upper side 291US of the inserting interlayer insulating film may be located on the same plane. Accordingly, the second conductive film 262 and the third conductive film 263 may be formed inside the recess 260R.

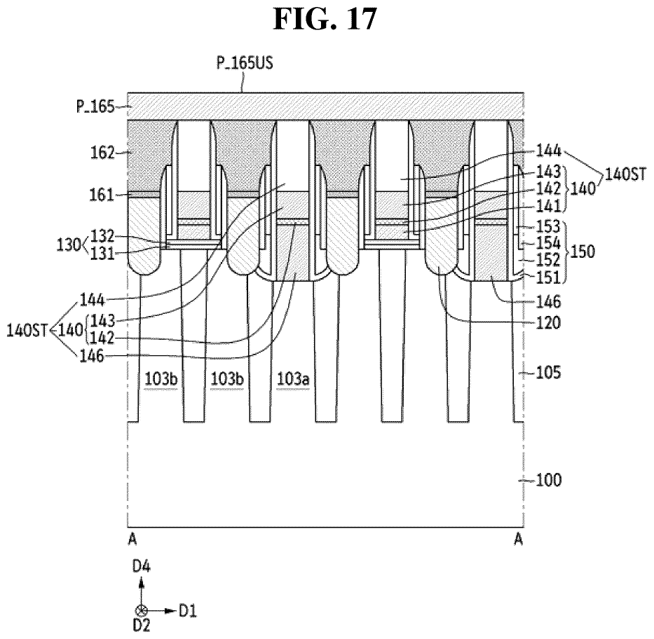

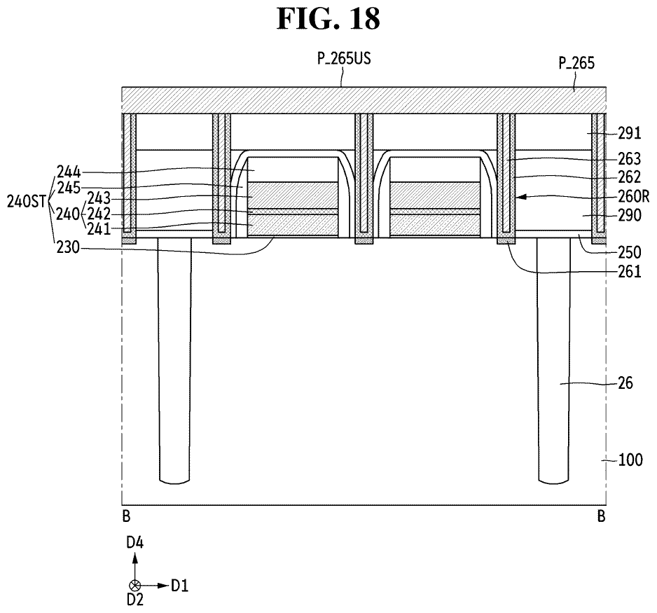

After that, referring to FIGS. 17 and 18, a pre-fourth conductive film P_165 may be formed on the first conductive film 162 of the cell region (20 of FIG. 1). The pre-fourth conductive film P_165 may include, for example, but is not limited to, tungsten (W). A pre-fifth conductive film P_265 may be formed on the third conductive film 263 of the peri region (24 of FIG. 1). The pre-fifth conductive film P_265 may include, for example, but is not limited to, tungsten (W).

A chemical mechanical polishing (CMP) and/or an etch-back process may be performed on the pre-fourth conductive film P_165 and the pre-fifth conductive film P_265. An upper side P_165US of the pre-fourth conductive film and an upper side P_265US of the pre-fifth conductive film may be located on the same plane.

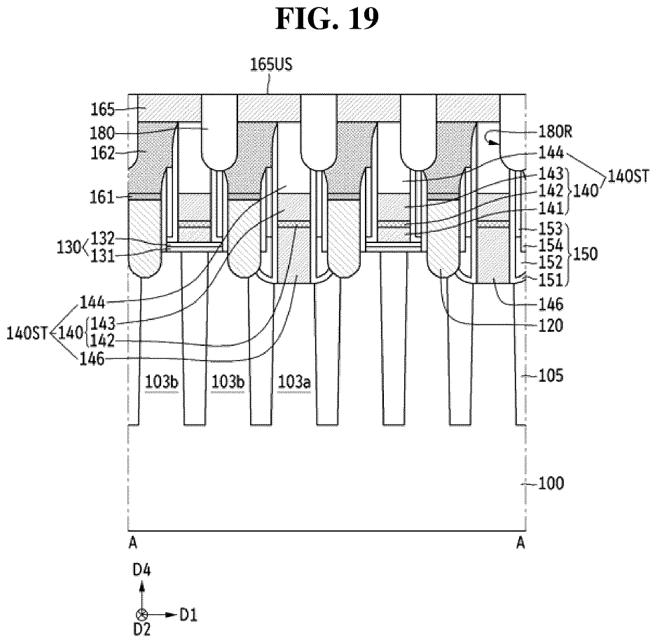

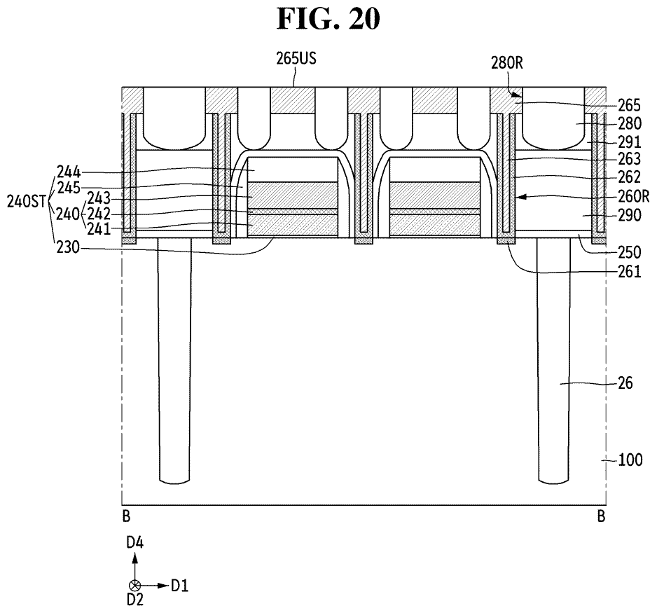

After that, referring to FIGS. 19 and 20, the pre-fourth conductive film (P_165 of FIG. 17) of the cell region (20 of FIG. 1) may be patterned to form a first recess 180R. The first separation pattern 180 may be formed in the first recess 180R. Accordingly, a fourth conductive film 165 separated by the first separation pattern 180 may be formed.

The pre-fifth conductive film (P_265 of FIG. 18) of the peri region (24 of FIG. 1) may be patterned to form a second recess 280R. The second separation pattern 280 may be formed inside the second recess 280R. A fifth conductive film 265 separated by the second separation pattern 280 may be formed, accordingly.

Next, referring to FIGS. 4 and 5, the data storage pattern 190 is formed on the upper side 165US of the fourth conductive film and the first separation pattern 180, and the second peri interlayer insulating film 293 may be formed on the upper side 265US of the fifth conductive film and the second separation pattern 280.

In the semiconductor memory device according to some embodiments, the process for forming the conductive material layers included in the storage structure 160ST of the cell region (20 of FIG. 1), and the process for processing the conductive material layers included in the peri contact plug 260 and the peri wiring line 265 of the peri region (24 of FIG. 1) may be performed separately. For example, after forming the conductive material layer included in the storage structure 160ST of the cell region (20 of FIG. 1), a cell protective film PS is formed in the cell region (20 of FIG. 1), and then a process for forming the conductive material layer included in the peri contact plug 260 of the peri region (24 of FIG. 1) may be performed. Accordingly, a level difference between the storage structure 160ST of the cell region (20 of FIG. 1) and the peri wiring line 265 of the peri region (24 of FIG. 1) may decrease. In addition, the conductive material layers included in the storage structure 160ST of the cell region (20 of FIG. 1), and the conductive material layers included in the peri contact plug 260 and the peri wiring line 265 of the peri region (24 of FIG. 1) may have different structures from each other.

Although the embodiments of the present disclosure have been described above with reference to the accompanying drawings, the present disclosure is not limited to the above embodiments, and may be fabricated in various different forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. A semiconductor memory device comprising:
a substrate which includes a cell region, and a peri region defined around the cell region, the cell region including a cell active region defined by a cell element separation film;
a plurality of bit line structures which extend in a first horizontal direction on each of the cell element separation film and the cell active region;
a storage contact which is connected to the cell active region between the plurality of bit line structures;
a first storage pad which is connected to the storage contact, on the storage contact;
a data storage pattern which is connected to the first storage pad;
a peri gate structure which is disposed on the substrate of the peri region; and
a peri contact plug which is disposed on both sides of the peri gate structure, and connected to the substrate,
wherein the first storage pad includes a first silicide film on the storage contact, and a first conductive film on the first silicide film,
the peri contact plug includes a recess that extends into the substrate in a vertical direction, a second silicide film on a bottom side of the recess, a second conductive film that extends along a side wall of the recess on the second silicide film, and a third conductive film that fills the inside of the recess on the second conductive film, and
a width of the first conductive film is different from a width of the second conductive film, in a second horizontal direction different from the first horizontal direction.

2. The semiconductor memory device of claim 1, further comprising:
a second storage pad which is connected to a data storage pattern, on the first storage pad; and
a peri wiring line which is connected to the peri contact plug, on the peri contact plug.

3. The semiconductor memory device of claim 2,
wherein an upper side of the second storage pad is located at a same level as a level of an upper side of the peri wiring line in the vertical direction.

4. The semiconductor memory device of claim 2,
wherein a lower side of the second storage pad is located at a same level as a level of a lower side of the peri wiring line in the vertical direction.

5. The semiconductor memory device of claim 2,
wherein each of the second storage pad, the third conductive film, and the peri wiring line includes a same metal material.

6. The semiconductor memory device of claim 1,
wherein an upper side of the first conductive film is located at a same level as a level of an upper side of the second conductive film in the vertical direction.

7. The semiconductor memory device of claim 1,
wherein the upper side of the first conductive film is located at a same level as a level of an upper side of the third conductive film in the vertical direction.

8. The semiconductor memory device of claim 1, further comprising:
an interlayer insulating film disposed on the peri gate structure,
wherein an upper side of the bit line structure is located at a same level as a level of an upper side of the interlayer insulating film in the vertical direction.

9. The semiconductor memory device of claim 1,
wherein a thickness of the first conductive film from the first silicide film is different from a thickness of the second conductive film from the second silicide film in the vertical direction.

10. The semiconductor memory device of claim 1,
wherein the first conductive film and the second conductive film include a same metal material.

11. The semiconductor memory device of claim 1,
wherein the first conductive film and the third conductive film include different metal materials from one another.

12. A semiconductor memory device comprising:
a substrate which includes a cell region, and a peri region defined around the cell region, the cell region including a cell active region defined by a cell element separation film;
a plurality of cell conductive lines which extend in a horizontal direction on each of the cell element separation film and the cell active region;
a storage contact which is connected to the cell active region between the plurality of cell conductive lines;
a first storage pad which is connected to the storage contact, on the storage contact;
a data storage pattern which is connected to the first storage pad;
a second storage pad between the first storage pad and the data storage pattern;
a peri gate structure which is disposed on the substrate of the peri region;
a peri contact plug which is disposed on both sides of the peri gate structure, and connected to the substrate; and
a peri wiring line which is connected to the peri contact plug, on the peri gate structure,
wherein the first storage pad includes a first silicide film on the storage contact, and a first conductive film on the first silicide film,
the peri contact plug includes a recess that extends into the substrate in a vertical direction, a second silicide film on a bottom side of the recess, a second conductive film that extends along a side wall of the recess on the second silicide film, and a third conductive film that fills the inside of the recess on the second conductive film, and
a thickness of the first conductive film is greater than a thickness of the second storage pad in the vertical direction.

13. The semiconductor memory device of claim 12,
wherein a thickness of the first conductive film from the first silicide film to a lower side of the second storage pad is different from a thickness of the second conductive film from the second silicide film to a lower side of the peri wiring line, in the vertical direction.

14. The semiconductor memory device of claim 12,
wherein a thickness of the second storage pad is equal to a thickness of the peri wiring line in the vertical direction.

15. The semiconductor memory device of claim 12,
wherein a thickness of the third conductive film is greater than a thickness of the first conductive film in the vertical direction.

16. The semiconductor memory device of claim 12,
wherein the first silicide film and the second silicide film are located at different levels from one another in the vertical direction.

17. The semiconductor memory device of claim 12,
wherein each of the first conductive film and the second conductive film includes titanium nitride (TiN).

18. The semiconductor memory device of claim 12,
wherein each of the second storage pad, the third conductive film, and the peri wiring line includes tungsten (W).

19. The semiconductor memory device of claim 12,
wherein the first conductive film includes titanium nitride (TiN), and the third conductive film includes tungsten (W).

20. A semiconductor memory device comprising:
a substrate which includes a cell region, and a peri region defined around the cell region, the cell region including a cell active region defined by a cell element separation film;
a plurality of bit line structures which extend in a horizontal direction on each of the cell element separation film and the cell active region;
a storage contact which is connected to the cell active region of the cell region between the plurality of bit line structures;
a storage pad structure which is connected to the storage contact, on the storage contact;
a data storage pattern which is connected to the storage pad structure;
a peri gate structure which is disposed on the substrate of the peri region;
an interlayer insulating film which is disposed on the peri gate structure;
a peri contact plug which is disposed on both sides of the peri gate structure, penetrates the interlayer insulating film, and is connected to the substrate; and
a peri wiring line which is connected to the peri contact plugs, on the peri gate structure,
wherein the storage pad structure includes a first storage pad on the storage contact, and a second storage pad between the first storage pad and the data storage pattern,
the first storage pad includes a first silicide film on the storage contact, and a first conductive film on the first silicide film,
the peri contact plug includes a recess that extends into the substrate in a vertical direction, a second silicide film on a bottom side of the recess, a second conductive film that extends along a side wall of the recess on the second silicide film, and a third conductive film that fills the inside of the recess on the second conductive film,
an upper side of the bit line structure is located at a same vertical level as a level of an upper side of the interlayer insulating film,
an upper side of the second storage pad is located at a same vertical level as a level of an upper side of the peri wiring line,
each of the first conductive film and the second conductive film includes titanium nitride (TiN), and
each of the second storage pad and the third conductive film includes tungsten (W).
